(19) United States
(12) Patent Application Publication
(10) Pub. No.: US 2014/0312314 A1
(43) Pub. Date: Oct. 23, 2014

(54) FLEXIBLE DISPLAY DEVICE AND MANUFACTURING METHOD THEREOF

(71) Applicant: Samsung Display Co., Ltd., Yongin-city (KR)

(72) Inventor: Hayk Khachatryan, Yongin-city (KR)

(73) Assignee: Samsung Display Co., Ltd., Yongin-city (KR)

(21) Appl. No.: 14/011,380

(22) Filed: Aug. 27, 2013

(30) Foreign Application Priority Data
Apr. 17, 2013 (KR) 10-2013-0042421

(51) Int. Cl. H01L 51/52; H01L 51/56

(52) U.S. Cl. CPC H01L 51/5237; H01L 51/56
USPC 257/40; 438/26

(57) ABSTRACT

A flexible display device and method of manufacturing the same is disclosed. In one aspect, the device includes: a substrate, a light-emitting display part formed on a first surface of the substrate, an encapsulation layer formed on the light-emitting display part, and an exfoliation layer formed on a second surface of the substrate. The exfoliation layer has a layer structure.

### CROSS-REFERENCE TO RELATED APPLICATIONS

This application claims the benefit of Korean Patent Application No. 10-2013-0042421, filed on Apr. 17, 2013, in the Korean Intellectual Property Office, the disclosure of which is incorporated herein in its entirety by reference.

### BACKGROUND

1. Field

The disclosed technology relates to a flexible display device and a manufacturing method thereof.

2. Description of the Related Technology

Recently, along with the development of display-related technology, flexible display devices capable of being folded or rolled in a roll shape have been researched and developed.

Since an organic light-emitting display panel has good characteristics in terms of a view angle, contrast, a response speed, power consumption, and the like, the application fields thereof have been expanded from personal portable devices, such as MP3 players, portable phones, and the like, to TVs. In addition, since an organic light-emitting display panel has a self-light-emitting characteristic, a separate light source is not necessary, and thus, a thickness and weight thereof can be reduced.

Such an organic light-emitting display panel can be implemented to be flexible using a plastic substrate. In general, a flexible organic light-emitting display panel may be formed by forming an organic light-emitting diode (OLED) and other components on a carrier substrate formed of a material, such as glass or the like, and debonding the carrier substrate from a plastic substrate.

### SUMMARY OF CERTAIN INVENTIVE ASPECTS

Embodiments of the disclosed technology relate to a flexible display device capable of preventing unnecessary adhesion of a substrate and a carrier substrate, and a manufacturing method thereof.

According to an aspect of the disclosed technology, a flexible display device includes: a substrate having a first surface and a second surface opposing the first surface, a light-emitting display part formed on the first surface of the substrate, an encapsulation layer formed on the light-emitting display part, and an exfoliation layer formed on the second surface of the substrate, where the exfoliation layer has a layer structure formed of a plurality of layers.

The exfoliation layer may be an inorganic material.

The exfoliation layer may be at least one of a hydrated magnesium silicate, a hexagonal boron nitride, graphite, and a molybdenum disulfide.

The exfoliation layer may be formed on substantially the entire second surface of the substrate.

A device and wiring layer may be formed between the substrate and the light-emitting display part.

The light-emitting display part may be an organic light-emitting display panel.

The exfoliation layer may be two layers and there may be a substantial van der Waals force between the two layers.

The exfoliation layer may have a small coefficient of friction.

The exfoliation layer may have a small coefficient of thermal expansion.

According to another aspect of the disclosed technology, a method of manufacturing a flexible display device includes: forming an exfoliation layer on a surface of a carrier substrate, where the exfoliation layer has a layer structure formed of a plurality of layers, disposing a surface of a substrate on the exfoliation layer, forming a light-emitting display part on the substrate, forming an encapsulation layer on the light-emitting display part, and removing the carrier substrate by splitting the exfoliation layer.

The exfoliation layer may be substantially formed of an inorganic material.

The exfoliation layer may be at least one of a hydrated magnesium silicate, a hexagonal boron nitride, graphite, and a molybdenum disulfide.

The exfoliation layer may be formed on the entire surface of the carrier substrate.

The method may further include aligning the carrier substrate and the substrate.

The bonding force between the carrier substrate and the substrate may be greater than the inter-layer bonding force of the exfoliation layer.

The exfoliation layer may be split between first and second layers in the layer structure.

The method may further include annealing at least one of the substrate or the carrier substrate.

A temperature of annealing may be about 300° C. or above.

The carrier substrate may be removed by a physical method.

The light-emitting display part may include an organic light-emitting display panel.

### BRIEF DESCRIPTION OF THE DRAWINGS

The above and other features and advantages of the disclosed technology will become more apparent by describing in detail certain embodiments thereof with reference to the attached drawings in which:

FIG. 1 is a schematic cross-sectional view of a flexible display device according to an embodiment of the disclosed technology;

FIG. 2 is a schematic cross-sectional view of one pixel region of a display panel part of the flexible display device of FIG. 1; and

FIGS. 3 to 5 are schematic cross-sectional views for describing a method of manufacturing the flexible display device of FIG. 1, according to an embodiment of the disclosed technology.

### DETAILED DESCRIPTION OF CERTAIN INVENTIVE EMBODIMENTS

The disclosed technology will now be described more fully with reference to the accompanying drawings, in which certain embodiments of the invention are shown. As used herein, the term “and/or” includes any and all combinations of one or more of the associated listed items. Generally, expressions such as “at least one of,” when preceding a list of elements, modify the entire list of elements and do not modify the individual elements of the list.

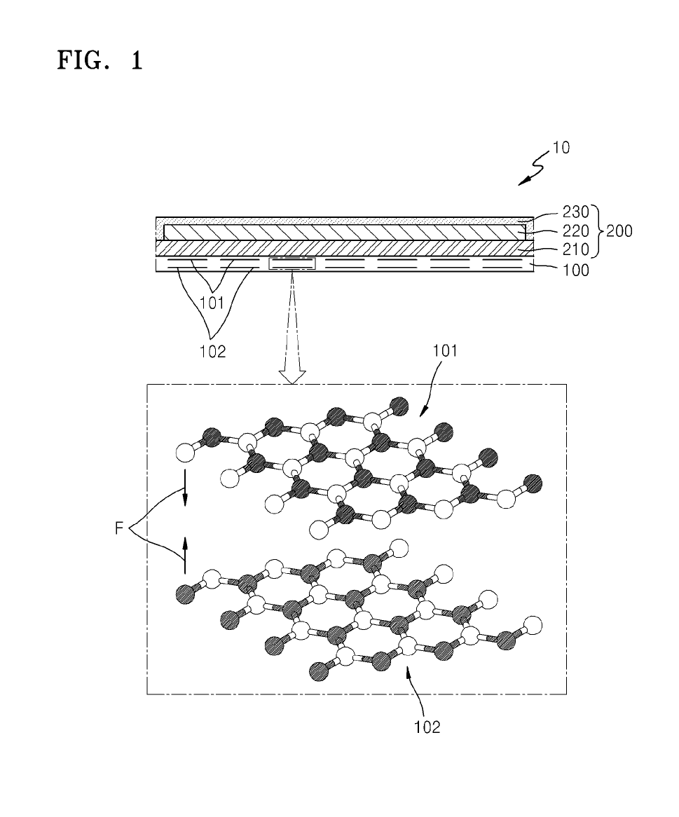

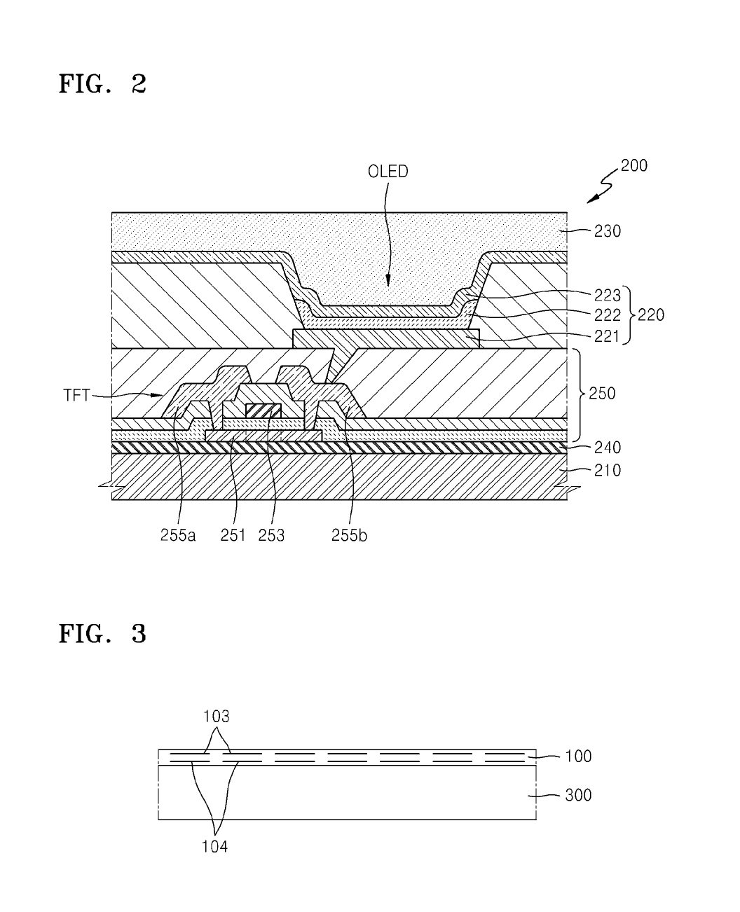

FIG. 1 is a schematic cross-sectional view of a flexible display device 10 according to an embodiment of the disclosed technology, and FIG. 2 is a schematic cross-sectional view of one pixel region of a display panel part 200 of the flexible display device 10 of FIG. 1.

Referring to FIGS. 1 and 2, the flexible display device 10 may include the display panel part 200 and an exfoliation layer 100 formed on a lower surface of the display panel part 200.

The display panel part 200 has a flexible property, and accordingly, can be folded or rolled. This in turn helps to keep or carry the display panel part 200. The display panel part 200 may be an organic light-emitting display panel, a liquid crystal display panel, or the like, and is not limited thereto. FIG. 2 shows an organic light-emitting display panel as one example of the display panel part 200.

Referring to FIG. 2, the display panel part 200 may include a substrate 210, a light-emitting display part OLED 220 disposed on a first surface of the substrate 210, and an encapsulation layer 230, which is disposed on the light-emitting display part OLED 220 to face the substrate 210 and seals the light-emitting display part OLED 220. In addition, a barrier film 240, and a device and wiring layer 250 may be sequentially formed between the substrate 210 and the light-emitting display part OLED 220.

The substrate 210 may be formed of a plastic material, such as, for example, acryl, polyethylene etherphthalate, polyethylene naphthalate, polycarbonate, polyarylate, polyetherimide, polyether sulfone, polyester, mylar, polyimide, or the like, so that the light-emitting display part OLED 220 has a flexible property. However, the substrate 210 is not limited thereto, and may also be formed of various other flexible materials.

The barrier film 240 may be disposed on the substrate 210. The barrier film 240 prevents foreign substances, such as for example, humidity, moisture and oxygen, from permeating a driving thin-film transistor TFT and/or the light-emitting display part OLED 220, by passing through the substrate 210.

The device and wiring layer 250 may be disposed on the barrier film 240 and may include the driving thin-film transistor TFT for driving the light-emitting display part OLED 220, a switching thin-film transistor (not shown), a capacitor, and wirings connected to the thin-film transistors and the capacitor.

The driving thin-film transistor TFT includes an active layer 251, a gate electrode 253, and source and drain electrodes 255a and 255b.

The light-emitting display part OLED 220 is disposed on the device and wiring layer 250. The light-emitting display part OLED 220 includes a pixel electrode 221, an organic light-emitting layer 222 disposed on the pixel electrode 221, and an opposing electrode 223 formed on the organic light-emitting layer 222.

In one embodiment, the pixel electrode 221 is an anode, and the opposing electrode 223 is a cathode. However, the disclosed technology is not limited thereto, and according to a method of driving the light-emitting display part OLED 220, the pixel electrode 221 may be a cathode, and the opposing electrode 223 may be an anode. Holes and electrons from the pixel electrode 221 and the opposing electrode 223 are doped into the organic light-emitting layer 222. When excitons obtained by bonding the doped holes and electrons drop from an excited state to a base state, light is emitted.

The pixel electrode 221 is electrically connected to the driving thin-film transistor TFT formed in the device and wiring layer 250.

Although a structure in which the light-emitting display part OLED 220 is disposed on the device and wiring layer 250 is set forth in one embodiment, the disclosed technology is not limited thereto, and can be modified in various forms, such as a structure in which the pixel electrode 221 of the light-emitting display part OLED 220 is formed in the same layer as the active layer 251 of the driving thin-film transistor TFT, a structure in which the pixel electrode 221 is formed in the same layer as the source and drain electrodes 255a and 255b, and so forth.

In addition, although the gate electrode 253 of the driving thin-film transistor TFT is disposed on the active layer 251 in one embodiment, the disclosed technology is not limited thereto, and the gate electrode 253 may be disposed below the active layer 251.

The pixel electrode 221 included in the light-emitting display part OLED 220 may be a reflective electrode, and may include a reflective film formed of one of: silver (Ag), magnesium (Mg), aluminum (Al), platinum (Pt), palladium (Pd), gold (Au), nickel (Ni), neodymium (Nd), iridium (Ir), chrome (Cr), or a compound thereof, and a transparent or translucent electrode layer formed on the reflective film.

The transparent or translucent electrode layer may include at least one of an indium tin oxide (ITO), an indium zinc oxide (IZO), a zinc oxide (ZnO), an indium oxide (In₂O₃), an indium gallium oxide (IGO), or an aluminum zinc oxide (AZO).

The opposing electrode 223 disposed to face the pixel electrode 221 may be a transparent or translucent electrode and may be formed by a metal thin film having a small work function, which may include lithium (Li), calcium (Ca), lithium fluoride/calcium (LiF/Ca), lithium fluoride/aluminum (LiF/Al), silver (Ag), magnesium (Mg), or a compound thereof. In addition, an auxiliary electrode layer or a bus electrode of a transparent electrode forming material (not shown), such as an ITO, an IZO, a ZnO, or an In₂O₃, may be further formed on the metal thin film. Thus, the opposing electrode 223 may transmit light emitted by the organic light-emitting layer 222.

The organic light-emitting layer 222 is disposed between the pixel electrode 221 and the opposing electrode 223, and may be formed of a low-molecular organic material or a high-molecular organic material.

In addition to the organic light-emitting layer 222, intermediate layers, such as a hole transport layer (HTL), a hole injection layer (HIL), an electron transport layer (ETL), an electron injection layer (EIL), and the like, may be selectively disposed between the pixel electrode 221 and the opposing electrode 223.

The organic light-emitting layer 222 may be a top-emission type in which the light emitted by the organic light-emitting layer 222 is directly emitted towards the opposing electrode 223, or is reflected by the pixel electrode 221, which is a reflective electrode, and is emitted towards the opposed electrode 223.

However, the light-emitting display part OLED 220 is not limited to the top-emission type, and the OLED 220 may be a bottom-emission type in which the light emitted by the organic light-emitting layer 222 is emitted towards the substrate 210. In this case, the pixel electrode 221 may be a transparent or translucent electrode, and the opposing electrode 223 may be a reflective electrode.

An encapsulation layer 230 may be disposed on the opposing electrode 223. The encapsulation layer 230 may be formed by a thin film including a multi-layer inorganic film, or including an inorganic film and an organic film. The encapsulation layer 230 may be formed by alternately laminating one or more organic layers, and one or more inorganic layers. The encapsulation layer 230 functions to prevent permeation of external humidity, moisture, oxygen, and the like, into the light-emitting display part OLED 220.

Returning to FIG. 1, the exfoliation layer 100 is formed on the second surface of the substrate 210. The exfoliation layer 100 may be formed of a material having a layer structure. The exfoliation layer 100 may be formed of an inorganic material. The exfoliation layer 100 may include a hydrated magnesium silicate, a hexagonal boron nitride, graphite (C), or a molybdenum disulfide. The hydrated magnesium silicate may be represented by the chemical formula Mg₃Si₄O₁₀(OH)₂ or H₂Mg₃(SiO₃)₄.

A layer structure of the hexagonal boron nitride is shown in FIG. 1 as an embodiment of the exfoliation layer 100. The hydrated magnesium silicate, the graphite (C), and the molybdenum disulfide may also have layer structures similar to the layer structure shown in FIG. 1.

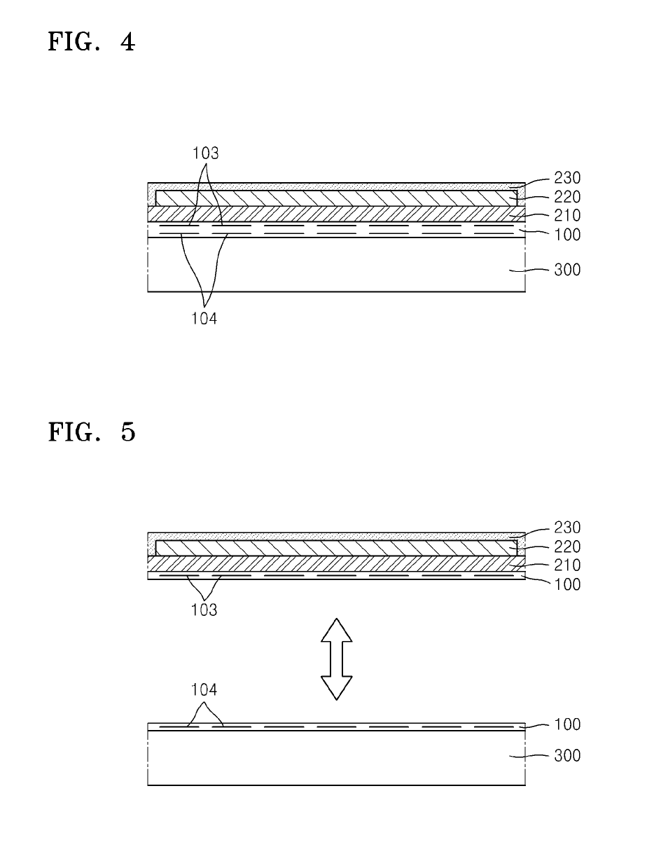

The exfoliation layer 100 may be formed in a layer structure in which two layers 101 and 102 are laminated. Although the two layers 101 and 102 are shown in FIG. 1, the exfoliation layer 100 may include one or more layers. An attractive force F acts between the two layers 101 and 102. The attractive force F of each of the two layers 101 and 102 may be a van der Waals force. The van der Waals force indicates an attractive force or a repulsive force between molecules (or parts in one molecule) rather than a covalent bond or an electrical interaction between ions. That is, when an instantaneous dipole is formed according to a motion of electrons in a nonpolar molecule, temporary polarization occurs in an adjacent molecule, thereby generating an induced dipole. An attractive force between the instantaneous dipole and the induced dipole is the van der Waals force. A layer structure may be formed by the two layers 101 and 102 overlapping in parallel by the attractive force F. According to the exfoliation layer 100 having a layer structure, a carrier substrate (see 300 of FIG. 3) may be more easily debonded as described below. That is, when the carrier substrate (300 of FIG. 3) is debonded in a physical method, an inter-layer bond in the layer structure is debonded, and thus the carrier substrate (300 of FIG. 3) may be more easily debonded.

In addition, the van der Waals force is relatively weaker than a force of the covalent bond or the electrical interaction between ions. Thus, the exfoliation layer 100, which can have a layer structure based on the van der Waals force, may have a small coefficient of friction. Accordingly, the exfoliation layer 100 may have a lubricant ability. In this case, the carrier substrate (300 of FIG. 3) may be easily covered by the exfoliation layer 100. In addition, the substrate 210 and the carrier substrate (300 of FIG. 3) can be aligned without scratching or injuring on the substrate 210 or the carrier substrate (300 of FIG. 3).

The exfoliation layer 100 may be formed on the whole substrate 210.

FIGS. 3 to 5 are schematic cross-sectional views for describing a method of manufacturing the flexible display device 10 of FIG. 1, according to an embodiment of the disclosed technology.

Hereinafter, a method of manufacturing the flexible display device 10, according to an embodiment of the disclosed technology, is be described with reference to FIGS. 3 to 5.

First, as shown in FIG. 3, the exfoliation layer 100 is formed on a carrier substrate 300.

The carrier substrate 300 is formed of a material, such as glass or the like, capable of withstanding a high temperature. In addition, the carrier substrate 300 is formed of a material that has a sufficient mechanical strength not to be deformed even when various devices or layers are formed thereon.

The exfoliation layer 100 may be formed by coating a material, such as a hydrated magnesium silicate, a hexagonal boron nitride, graphite (C), a molybdenum disulfide, or the like, on the carrier substrate 300 by spin coating, dip coating, slit coating, or the like. The exfoliation layer 100, which can have a layer structure by the van der Waals force, may have a small coefficient of friction. Accordingly, the exfoliation layer 100 may have a lubricant ability. In this case, the carrier substrate 300 may be easily covered by the exfoliation layer 100.

The exfoliation layer 100 may have a layer structure in which a first layer 103 and a second layer 104 are included. An attractive force acts between the first layer 103 and the second layer 104. The attractive force of each of the first 103 and second 104 layers may be the van der Waals force. Although FIG. 3 shows the first and second layers 103 and 104, the exfoliation layer 100 may comprise more than two layers. That is, at least one other layer may be further included on the first layer 103 or below the second layer 104.

The exfoliation layer 100 may be formed on the whole substrate 210. Conventionally, when a temperature of the substrate 210 or the carrier substrate 300 reaches about 300° C. or above, permanent bonding of the substrate 210 and the carrier substrate 300 may occur. By forming the exfoliation layer 100 on the whole substrate 210, the substrate 210 and the carrier substrate 300 can be generally debonded from each other. Accordingly, the bonding between the substrate 210 and the carrier substrate 300 can be prevented.

Next, as shown in FIG. 4, the substrate 210, the light-emitting display part OLED 220, and the encapsulation layer 230 are sequentially formed on the exfoliation layer 100.

The substrate 210 may be formed of a plastic material, such as acryl, polyethylene etherphthalate, polyethylene naphthalate, polycarbonate, polyarylate, polyetherimide, polyether sulfone, polyester, mylar, polyimide, or the like.

After disposing the substrate 210 on the exfoliation layer 100, the substrate 210 and the carrier substrate 300 are aligned. Since the exfoliation layer 100 has a layer structure, the exfoliation layer 100 may have a lubricant ability. Accordingly, the substrate 210 and the carrier substrate 300 can be aligned without scratching or injuring the substrate 210 or the carrier substrate 300.

After aligning the substrate 210 and the carrier substrate 300, the exfoliation layer 100 is bonded to the carrier substrate 300 and the substrate 210. That is, one surface of the exfoliation layer 100 is bonded to the substrate 210, and the other surface of the exfoliation layer 100 is bonded to the carrier substrate 300. The substrate 210 and the carrier substrate 300 are temporarily bonded to each other by interposing the exfoliation layer 100 therebetween. According to an embodiment of the disclosed technology, when a hydrated magnesium silicate (Mg₃Si₄O₁₀(OH)₂) is used for the exfoliation layer 100, since the —OH groups of the exfoliation layer 100 react with the —OH groups of the substrate 210 and the carrier substrate 300, the exfoliation layer 100 can be bonded to the carrier substrate 300 and the substrate 210.

A bonding force between the exfoliation layer 100 and the substrates 210 and 300 is preferably greater than an attractive force between every two layers in the layer structure. That is, the bonding force between the exfoliation layer 100 and the substrates 210 and 300 is preferably greater than the attractive force between the first layer 103 and the second layer 104.

The light-emitting display part OLED 220 is formed on the substrate 210 by sequentially forming a pixel electrode 221, an organic light-emitting layer 222, and an opposing electrode 223, and the encapsulation layer 230 is formed on the light-emitting display part OLED 220 to cover the light-emitting display part OLED 220. The encapsulation layer 230 may be formed by a thin film including a multi-layer inorganic film or including an inorganic film and an organic film. In addition, the encapsulation layer 230 may be formed by alternately laminating one or more organic layers and one or more inorganic layers.

In the process of sequentially forming the pixel electrode 221, the organic light-emitting layer 222, and the opposing electrode 223, a process of annealing the substrate 210 or the carrier substrate 300 may be included. A temperature of the substrate 210 or the carrier substrate 300 may be about 300° C. or above by the annealing process. Conventionally, when a temperature of the substrate 210 or the carrier substrate 300 is about 300° C. or above, the permanent bonding of the substrate 210 and the carrier substrate 300 may occur. According to an embodiment of the disclosed technology, by disposing the exfoliation layer 100 of a layer structure between the substrate 210 and the carrier substrate 300, the permanent bonding of the substrate 210 and the carrier substrate 300 does not occur even though a temperature of the substrate 210 or the carrier substrate 300 is at about 300° C. or above.

In addition, the exfoliation layer 100 may have a small coefficient of thermal expansion. In more detail, the hexagonal boron nitride may have a coefficient of thermal expansion that is less than about 0. Since the exfoliation layer 100 has a small coefficient of thermal expansion, deformation of the exfoliation layer 100 due to heat is small, and thus, the process of annealing the substrate 210 or the carrier substrate 300 may be carried out without any problem due to thermal expansion of the exfoliation layer 100.

Next, as shown in FIG. 5, the carrier substrate 300 is debonded from the substrate 210.

The carrier substrate 300 may be debonded from the substrate 210 in a physical method.

The exfoliation layer 100 has a layer structure and includes the first layer 103 and the second layer 104, and the bonding force between the substrates 210 and 300 may be greater than the attractive force between the first layer 103 and the second layer 104. Accordingly, the bonding between the first and second layers 103 and 104 of the exfoliation layer 100 may be debonded by a physical method, thereby debonding the carrier substrate 300 from the substrate 210. That is, when the inter-layer bonding in the layer structure of the exfoliation layer 100 is debonded, the exfoliation layer 100 is divided into two, thereby easily separating the carrier substrate 300. Accordingly, the detachment yield of the carrier substrate 300 may be improved.

The configuration and method of the embodiments described above is not limitedly applied to the flexible display device 10 according to the disclosed technology, and the embodiments may be formed by selectively combining all or a portion of the embodiments so that various modifications are made.

According to an embodiment of the disclosed technology, by forming an exfoliation layer on one surface of a substrate, the permanent bonding of the substrate and a carrier substrate can be prevented.

While the present invention has been particularly shown and described with reference to certain embodiments thereof, it will be understood by those of ordinary skill in the art that various changes in form and details may be made therein without departing from the spirit and scope of the present invention as defined by the following claims.

What is claimed is:

1. A flexible display device comprising:
a substrate having a first surface and a second surface opposing the first surface;
a light-emitting display part formed on the first surface of the substrate;
an encapsulation layer formed on the light-emitting display part; and
an exfoliation layer formed on the second surface of the substrate,
wherein the exfoliation layer has a layer structure formed of a plurality of layers.

2. The flexible display device of claim 1, wherein the exfoliation layer is substantially formed of an inorganic material.

3. The flexible display device of claim 1, wherein the exfoliation layer is at least one of a hydrated magnesium silicate, a hexagonal boron nitride, graphite, and a molybdenum disulfide.

4. The flexible display device of claim 1, wherein the exfoliation layer is formed on substantially the entire second surface of the substrate.

5. The flexible display device of claim 1, wherein a device and wiring layer is formed between the substrate and the light-emitting display part.

6. The flexible display device of claim 1, wherein the light-emitting display part comprises an organic light-emitting display panel.

7. The flexible display device of claim 1, wherein the exfoliation layer is two layers and there is a substantial van der Waals force between the two layers.

8. The flexible display device of claim 1, wherein the exfoliation layer has a small coefficient of friction.

9. The flexible display device of claim 1, wherein the exfoliation layer has a small coefficient of thermal expansion.

10. A method of manufacturing a flexible display device, the method comprising:
forming an exfoliation layer on a surface of a carrier substrate, wherein the exfoliation layer has a layer structure formed of a plurality of layers;
disposing a surface of a substrate on the exfoliation layer;
forming a light-emitting display part on the substrate;
forming an encapsulation layer on the light-emitting display part; and
removing the carrier substrate by splitting the exfoliation layer.

11. The method of claim 10, wherein the exfoliation layer is substantially formed of an inorganic material.

12. The method of claim 10, wherein the exfoliation layer is formed of at least one of a hydrated magnesium silicate, a hexagonal boron nitride, graphite, and a molybdenum disulfide.

13. The method of claim 10, wherein the exfoliation layer is formed on the entire surface of the carrier substrate.

14. The method of claim 10, further comprising aligning the carrier substrate and the substrate.

15. The method of claim 10, wherein the bonding force between the carrier substrate and the substrate is greater than the inter-layer bonding force of the exfoliation layer.

16. The method of claim 15, wherein the exfoliation layer is split between first and second layers in the layer structure.

17. The method of claim 10, further comprising annealing at least one of the substrate or the carrier substrate.

18. The method of claim 17, wherein a temperature of annealing is about 300° C. or above.

19. The method of claim 10, wherein the carrier substrate is removed by a physical method.

20. The method of claim 13, wherein the light-emitting display part comprises an organic light-emitting display panel.
